(19) United States
(12) Patent Application Publication
(10) Pub. No.: US 2008/0173972 A1
(43) Pub. Date: Jul. 24, 2008

(54) METHOD OF WAFER THINNING

(75) Inventor: Gerald W. Gibson, Danbury, CT (US)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/624,824

(22) Filed: Jan. 19, 2007

(51) Int. Cl. H01L 23/00; H01L 21/66; H01L 21/302

(52) U.S. Cl. 257/506; 438/692; 438/16; 257/E23.001; 257/E21.521; 257/E21.214

(57) ABSTRACT

A method for thinning a semiconductor wafer, the method includes selecting a semiconductor wafer having a buried stop layer; and planarizing the semiconductor wafer to the buried stop layer to produce a thin semiconductor wafer.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention relates to thinning semiconductor wafers.

2. Description of the Related Art

A miniaturized electronic circuit may be manufactured into a semiconductor wafer. The miniaturized electronic circuit is referred to as an integrated circuit. The integrated circuits may be stacked vertically in order to save space.

It is advantageous to make the semiconductor wafers thin for stacked integrated circuits. One reason is to improve thermal conductance. Another reason is to minimize interference with interconnections of the integrated circuits.

Currently, a bulk substrate material such as silicon is temporarily bonded to a semiconductor wafer. The bulk substrate material acts as a handle for the semiconductor wafer during a thinning process. Typically, the semiconductor wafer is thinned using a back grinding process. The back grinding process is performed in a series of steps. Each of the steps uses progressively finer abrasives. The back grinding process is referred to as a “blind” process. The back grinding process relies on a uniformity of thickness of the bulk substrate material to achieve a uniform thickness of the semiconductor wafer. Low uniformity of thickness may limit the amount to which the semiconductor wafer may be thinned. Ultimately, thickness of the semiconductor wafers after the back grinding process is limited to several tens of microns.

What is needed is a method to make thinner semiconductor wafers.

### SUMMARY OF THE INVENTION

The shortcomings of the prior art are overcome and additional advantages are provided through a method for thinning a semiconductor wafer, the method includes selecting a semiconductor wafer having a buried stop layer and planarizing the semiconductor wafer to the buried stop layer to produce a thin semiconductor wafer.

Also disclosed is a semiconductor wafer including a buried stop layer adapted for providing indication for terminating a thinning process.

Further disclosed is a method for thinning a semiconductor wafer, the method includes determining a desired thickness for the buried stop layer by evaluating at least one of characteristics of a thin semiconductor wafer, design parameters for interconnections with the thin semiconductor wafer and design parameters for thermal conductance of the thin semiconductor wafer; etching a buried stop layer trench in the semiconductor wafer according to the thickness; filling the buried stop layer trench with a marker material; and planarizing the semiconductor wafer to the buried stop layer by performing at least one of mechanical back grinding, uniform reactive ion etching, and chemical-mechanical planarization to produce the thin semiconductor wafer.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### TECHNICAL EFFECTS

As a result of the summarized invention, technically we have achieved a solution with a method for thinning a semiconductor wafer, the method includes selecting a semiconductor wafer having a buried stop layer and planarizing the semiconductor wafer to the buried stop layer to produce a thin semiconductor wafer.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates a side view of a semiconductor wafer before thinning;

FIG. 2 illustrates a side view of the semiconductor wafer after a mechanical back grinding process;

FIG. 3 illustrates a side view of the semiconductor wafer after a reactive ion etching process;

FIG. 4 illustrates a side view of the semiconductor wafer after a chemical-mechanical planarization process; and

FIG. 5 presents an exemplary method for thinning the semiconductor wafer.

The detailed description explains the preferred embodiments of the invention, together with advantages and features, by way of example with reference to the drawings.

### DETAILED DESCRIPTION OF THE INVENTION

The teachings herein provide a method for fabricating thin seminconductor wafers. The method makes use of an embedded marker that is incorporated within each semiconductor wafer. During the fabrication process, each wafer having the embedded marker is thinned (using conventional techniques, for example, back grinding). When the marker is identified, the thinning process is terminated. Fabrication of thin semiconductor wafers in this manner provides for wafers having greater uniformity of thickness and strength than previously achieved. The greater uniformity of thickness of the thin semiconductor wafer results from an accurate placement of the embedded marker. The tolerance of the dimension for the placement (depth) is smaller than the variations of thickness of the bulk substrate material. Before the method is described in detail certain definitions are provided.

The term “thinning” relates to removing material from at least one side of the semiconductor wafer. The term “thin” relates to the thickness of the semiconductor wafer resulting from thinning the semiconductor wafer in accordance with the teachings herein. A thin semiconductor wafer may be approximately 10 microns thick. The term “uniformity of thickness” relates to variations in a thickness. A high uniformity of thickness relates to small variations in the thickness.

The term “shallow trench isolation circuit” relates to a section of an integrated circuit. The section is at least partially surrounded by a shallow trench filled with an insulating material such as silicon dioxide. Shallow trench isolation provides for increased circuit density. The trenches are typically formed by etching. In general, the etching is performed by a photolithography process. The term “silicon on insulator” relates to a form of integrated circuit construction. A layer of silicon is etched with electronic circuitry. The layer is insulated from the rest of the semiconductor wafer by an insulating layer. The insulating layer used with the shallow trench isolation circuit is referred to as a “box.”

The term “planarizing” relates to the process of thinning the semiconductor wafer. A surface of the semiconductor wafer being thinned is formed into a planar surface. The term “uniform reactive ion etching” relates to using a plasma to remove a uniform thickness of the semiconductor wafer. The term “chemical-mechanical planarization” relates to removing semiconductor wafer material using an abrasive and a corrosive chemical slurry in conjunction with a dynamic polishing pad.

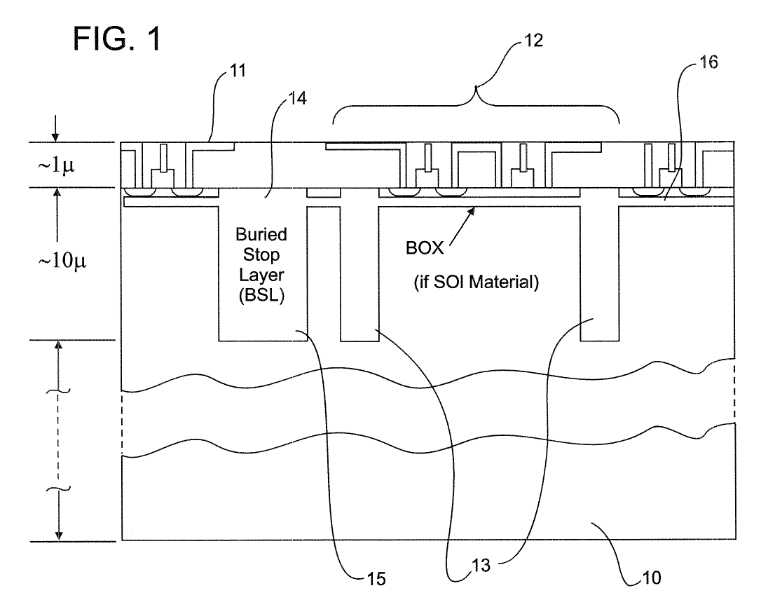

FIG. 1 illustrates a side view of one example of a semiconductor wafer 10 before planarizing. Fabricated atop the semiconductor wafer 10 is electronic circuitry 11. A shallow trench isolation circuit 12 is formed by shallow trenches 13. The shallow trench isolation circuit 12 includes the electronic circuitry 11 that is bounded by the shallow trenches 13. A marker known as a buried stop layer 14 is imbedded in the semiconductor wafer 10. The buried stop layer 14 is formed from a buried stop layer trench 15. The buried stop layer trench 15 may be fabricated by the same process used to fabricate the shallow trenches 13. Also, in one embodiment the shallow trenches 13 filled with an insulating material may be used as the buried stop layer 14. Typically, material for the buried stop layer trench 14 is the same as material used to fill the shallow trenches 13. Exemplary material includes silicon dioxide. FIG. 1 also illustrates one example of using silicon on insulator (SOI) construction. An SOI insulating layer 16 insulates the electronic circuitry 11 from the semiconductor wafer 10.

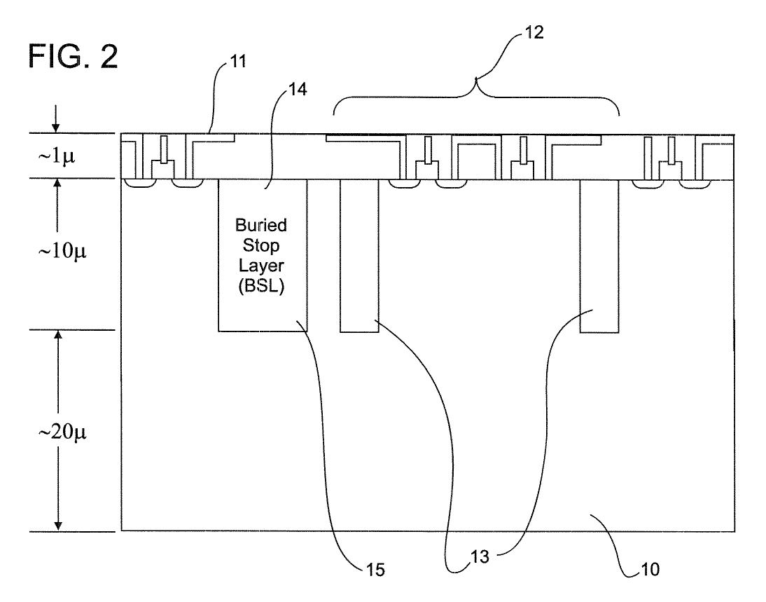

Typically, planarizing the semiconductor wafer 10 includes several steps. A first step includes a mechanical back grinding process. The mechanical back grinding process typically thins the semiconductor wafer 10 to a thickness of approximately 30 microns. FIG. 2 illustrates a side view of the semiconductor wafer 10 after the mechanical back grinding process.

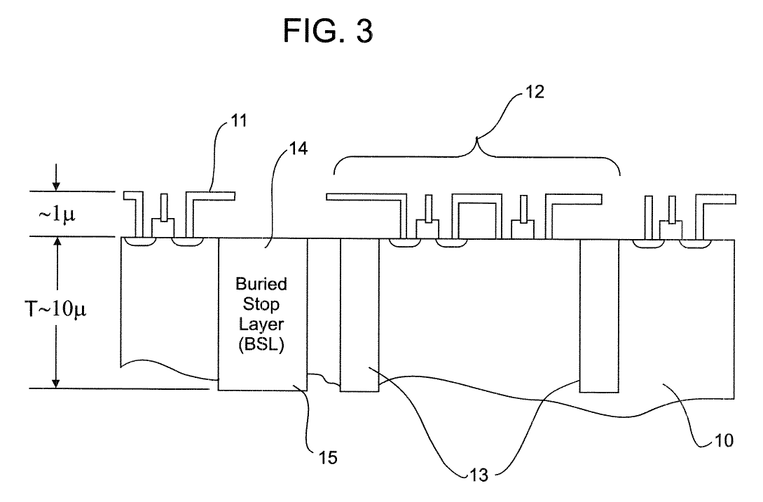

A second step typically includes a uniform reactive ion etching process. The uniform reactive ion etching process further removes material from the semiconductor wafer 10 until at least one buried stop layer 14 is identified. FIG. 3 illustrates a side view of the semiconductor wafer 10 after the uniform reactive ion etching process is applied. The uniform reactive ion etching process typically thins the semiconductor wafer 10 to a thickness T of approximately 10 microns. The uniform reactive ion etching process may not completely remove all of the material covering the buried stop layer 14.

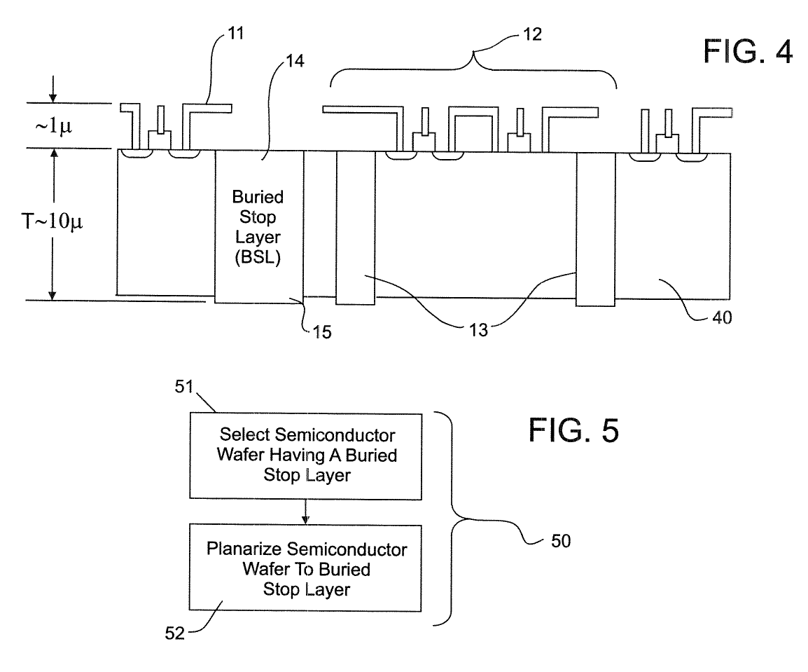

A third step typically includes removing the remainder of any material covering the buried stop layer 14 to produce the thin semiconductor wafer. The third step is typically performed using a chemical-mechanical planarization process. FIG. 4 illustrates a side view of the semiconductor wafer 10 after it has been thinned to produce a thin semiconductor wafer 40.

FIG. 5 presents an exemplary method 50 for thinning the semiconductor wafer 10 to produce the thin semiconductor wafer 40. A first step 51 includes selecting a semiconductor wafer 10 having a buried stop layer 14. The first step 51 may include determining a desired thickness for the buried stop layer 14. The desired thickness may be determined by evaluating at least one of characteristics of the thin semiconductor wafer 40, design parameters for interconnections of the thin semiconductor wafer 40, and design parameters for thermal conductance of the thin semiconductor 40. The first step 51 may include fabricating the buried stop layer 14. Fabricating the buried stop layer 14 may include etching at least one buried stop layer trench 15. The etching may be performed as part of a process fabricating the shallow trenches 13 for the shallow trench isolation circuit 12. The first step 51 may include filling the buried stop layer trench 15 with a contrasting marker material. The contrasting marker material provides contrast with respect to the semiconductor wafer 10. The marker material may be the same material used to fill the shallow trenches 13. A second step 52 includes planarizing the semiconductor wafer 10 until the buried stop layer 14 is reached. The planarizing may be accomplished by at least one of the mechanical back grinding process, the uniform reactive ion etching process, and the chemical-mechanical planarization process.

Various embodiments of the method 50 may be had. In one embodiment, the method 50 is used to produce the thin semiconductor wafer 40 without the electronic circuitry 11. In another embodiment, the method 50 is used to produce the thin semiconductor wafer 40 including the electronic circuitry 11.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

1. A method for thinning a semiconductor wafer, the method comprising:
selecting a semiconductor wafer having a buried stop layer comprising a buried stop layer trench filled with a marker material that is insulating; and
planarizing the semiconductor wafer to the buried stop layer to produce a thin semiconductor wafer.

2. The method as in claim 1, wherein selecting comprises:
determining a desired thickness for the buried stop layer; and
fabricating a buried stop layer in the semiconductor wafer according to the desired thickness.

3. The method as in claim 2, wherein determining comprises evaluating at least one of characteristics of the thin semiconductor wafer, design parameters for interconnections of the thin semiconductor wafer, and design parameters for thermal conductance of the thin semiconductor wafer.

4. The method as in claim 2 wherein, fabricating comprises:
making a buried stop layer trench; and
filling the buried stop layer trench with an insulating marker material.

5. The method as in claim 4 wherein, making comprises etching the buried stop layer trench.

6. The method as in claim 1 wherein, planarizing comprises:
thinning the wafer to a thickness of approximately 30 microns using mechanical backgrinding,
thinning the wafer until the buried stop layer is identified using uniform reactive ion etching, and
removing a remainder of any wafer material covering the buried stop layer using chemical-mechanical planarization.

7. A semiconductor wafer comprising a buried stop layer adapted for providing indication for terminating a thinning process, the buried stop layer comprising a buried stop layer trench filled with a marker material that is insulating.

8. (canceled)

9. The semiconductor wafer as in claim 7, further comprising silicon dioxide as athe marker material in the buried stop layer trench.

10. The semiconductor wafer as in claim 7, further comprising the marker material contrasting with respect to the semiconductor wafer.

11. The semiconductor wafer as in claim 7, further comprising electronic circuitry.

12. The semiconductor wafer as in claim 7, further comprising a shallow trench isolation circuit.

13. The semiconductor wafer as in claim 7, further comprising silicon on insulator construction.

14. A method for thinning a semiconductor wafer, the method comprising:
determining a desired thickness for the buried stop layer by evaluating at least one of characteristics of a thin semiconductor wafer, design parameters for interconnections with the thin semiconductor wafer and design parameters for thermal conductance of the thin semiconductor wafer;
etching a buried stop layer trench in the semiconductor wafer according to the desired thickness;
filling the buried stop layer trench with a contrasting marker material that contrasts with the wafer and is an insulating material; and
planarizing the semiconductor wafer to the buried stop layer the planarizing comprising: thinning the wafer to a thickness of approximately 30 microns using mechanical backgrinding, thinning the wafer until the buried stop layer is identified using uniform reactive ion etching, and removing a remainder of any wafer material covering the buried stop layer using chemical-mechanical planarization to produce the thin semiconductor wafer.

15. The method as in claim 4, wherein the marker material comprises a contrasting marker material that provides contrast with respect to the semiconductor wafer.
